(19) United States
(12) Patent Application Publication
(10) Pub. No.: US 2025/0242692 A1
(43) Pub. Date: Jul. 31, 2025

(54) VEHICLE DISPLAY DEVICE

(71) Applicant: LG Display Co., Ltd., Seoul (KR)

(72) Inventors: Minwoo KIM, Gumi-si (KR); Hakyeol KWON, Gumi-si (KR)

(73) Assignee: LG Display Co., Ltd., Seoul (KR)

(21) Appl. No.: 18/915,873

(22) Filed: Oct. 15, 2024

(30) Foreign Application Priority Data
Jan. 30, 2024 (KR) 10-2024-0013929

(51) Int. Cl. B60K 35/22; B60K 35/60; H10K 59/80

(52) U.S. Cl. CPC B60K 35/22; B60K 35/60; H10K 59/8722; H10K 59/8792; B60K 2360/84

(57) ABSTRACT

Disclosed is a vehicle display device in which a heat dissipation structure is built inside a metal plate disposed on a back surface of the display panel, thereby efficiently dissipating heat generated from the display panel. To this end, a plurality of metal layers constitute a plate of the display panel in a display module mounted on a dashboard of a vehicle, and a foam layer having an air vent capable of heat exchange formed therein is disposed between adjacent ones of the plurality of metal layers. Therefore, heat generated from the vehicle display device is efficiently dissipated through flow of air inside the plate.

### CROSS-REFERENCE TO RELATED APPLICATION

This application claims the benefit of and priority to Korean Patent Application No. 10-2024-0013929 filed on Jan. 30, 2024, the entire contents of which are incorporated herein by reference for all purposes as if fully set forth herein.

### BACKGROUND

### 1. Technical Field

The present disclosure relates to a display device, and particularly to, for example, without limitation, a vehicle display device mounted on a moving vehicle.

### 2. Description of the Related Art

In recent years, the uses of display devices have become more diverse, their thickness has become thinner and their weight has become lighter, the scope of their use is expanding, and the display devices are used in various fields. Thus, the demand for display devices that provide high-quality images is increasing.

Recently, a vehicle display device mounted inside a vehicle to provide an image to a user sitting in the driver's seat or passenger seat has become popular.

The vehicle display device includes a display area (Active Area; hereinafter referred to as AA) that displays a screen and a non-display area (Non-active Area hereinafter referred to as NA) formed along an outer edge of the display area. The display device includes a display panel to display the screen, and further requires various additional components such as a driving integrated circuit or a circuit board. The additional components may be located in the non-display area, or various connection components such as a flexible printed circuit board for connecting additional components may be located in the non-display area.

The non-display area is referred to as a bezel area. When the bezel area is thick, the user's gaze is distracted. When the bezel area is thin, the user's gaze is fixed to the screen of the display area, which may increase immersion.

The description of the related art should not be assumed to be prior art merely because it is mentioned in or associated with this section. The description of the related art includes information that describes one or more aspects of the subject technology, and the description in this section does not limit the invention.

### SUMMARY

The vehicle display device may mainly operate when the vehicle is driving. When the driver touches the screen of the display panel, the vehicle display device operates under an input corresponding to the touch, such that a surface temperature of a cover glass (hereinafter referred to as CG) located at the top of the screen increases.

Therefore, when a vehicle display device displays an image under emission of an organic light-emitting element (OLED), heat is generated during the operation of the display panel and the IC. Thus, in order to effectively dissipate the heat generated during the operation of the panel and the IC to an outside, a metal plate is attached to a back surface (bottom surface) of the display panel to manage the surface temperature of the CG.

Recently, with the spread of high-luminance vehicle display devices, the surface temperature of the CG has increased further during the operation of the display device. Thus, there are requests from customers who use the display device to lower the surface temperature.

The inventors of the present disclosure have recognized the problems and needs of the related art and the aforementioned requirements, have performed extensive research and experiments, and have developed a vehicle display device in which a heat dissipation structure is built inside a metal plate disposed on a back surface of the display panel, thereby efficiently dissipating heat generated from the display panel.

Furthermore, one or more aspects of the present disclosure are to provide a vehicle display device in which a plurality of metal layers constitute a plate of the display panel in a display module mounted on a dashboard of a vehicle, and a foam layer having an air vent capable of heat exchange formed therein is disposed between adjacent ones of the plurality of metal layers.

Furthermore, one or more aspects of the present disclosure are to provide a vehicle display device in which a black coating layer is applied to the uppermost metal layer among the plurality of metal layers constituting the plate to achieve a heat dissipation function of heat conduction and radiation, and in addition, a thermally-conductive pressure-sensitive adhesive is disposed to achieve heat conduction between layers.

Aspects according to the present disclosure are not limited to the above-mentioned aspects. Other aspects and advantages according to the present disclosure that are not mentioned may be understood based on following descriptions, and may be more clearly understood based on embodiments according to the present disclosure. Further, it will be easily understood that the aspects and advantages according to the present disclosure may be realized using means shown in the claims or combinations thereof.

In order to achieve the above aspects of the present disclosure, a vehicle display device in one or more examples includes a display panel disposed on a dashboard of a vehicle, wherein the display panel includes a display area in which a plurality of sub-pixels are arranged, and a non-display area surrounding the display area; and a plate disposed under the display panel so as to support the display panel, wherein the plate includes a plurality of metal layers, and further includes a foam layer disposed between adjacent ones of the plurality of metal layers, wherein the foam layer has an air vent formed therein.

According to an example embodiment of the present disclosure, the heat dissipation structure may be built inside the plate supporting the display panel in the vehicle display device, thereby efficiently dissipating the heat generated from the panel and the driving IC.

Furthermore, according to an example embodiment of the present disclosure, the plurality of metal layers are disposed inside the plate supporting the display panel in the vehicle display device, and the foam layer having the air vent for air flow defined therein is disposed between adjacent ones of the plurality of metal layers, thereby efficiently dissipating heat generated from the vehicle display device through the air flow.

Furthermore, according to an example embodiment of the present disclosure, carbon powders may be added to the foam layer between adjacent ones of the plurality of metal layers inside the plate of the vehicle display device, thereby doubling the heat transfer effect. Thus, the heat generated from the vehicle display device may be efficiently dissipated using the transfer between the metal layers.

Furthermore, according to an example embodiment of the present disclosure, the metal layers may be stacked inside the plate of the vehicle display device. Thus, the heat dissipation effect may be maximized.

Furthermore, according to an example embodiment of the present disclosure, the heat dissipation structure may be built inside the plate of the vehicle display device. Thus, a separate heat dissipation device is not required, thereby simplifying a manufacturing process.

Furthermore, according to an example embodiment of the present disclosure, the heat generated during operation of the vehicle display device is efficiently dissipated through the heat dissipation structure inside the plate. Thus, a separate heat dissipation component is not required, thereby simplifying a manufacturing process. Thus, a manufacturing cost may be reduced, and production energy may be reduced. Quality improvement may be realized.

The effects of the present disclosure are not limited to the effects as mentioned above, and other effects not mentioned above will be clearly understood by those skilled in the art from following descriptions.

In addition to the above-described effects, the specific effects of the present disclosure are described below while describing specific details for implementing the embodiments of the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a diagram schematically showing a vehicle equipped with a vehicle display device according to an example embodiment of the present disclosure.

FIG. 2 is a drawing schematically showing an outer appearance of a vehicle display device according to an example embodiment of the present disclosure.

FIG. 3 is an exploded perspective view showing a vehicle display device according to an example embodiment of the present disclosure.

FIG. 4 is a block diagram schematically showing an internal configuration of a vehicle display device according to an example embodiment of the present disclosure.

FIG. 5 is a diagram schematically showing a configuration of a vehicle display device according to an example embodiment of the present disclosure.

FIG. 6 is a diagram showing an example circuit configuration of a sub-pixel of FIG. 4 in a vehicle display device according to an example embodiment of the present disclosure.

FIG. 7 is a diagram showing a cutting line cutting a display module according to an example embodiment of the present disclosure.

FIG. 8 is a cross-sectional view of a display module according to an example embodiment of the present disclosure as cut along a line C-C′.

FIG. 9 is a structural diagram showing a B portion of FIG. 8 in more detail in a display module according to an example embodiment of the present disclosure.

FIG. 10 is a diagram showing an example in which multiple holes are formed inside a plate according to an example embodiment of the present disclosure.

FIG. 11 is a diagram showing an example in which a foam layer containing carbon powders is disposed inside a plate according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments”, “examples”, “aspects”, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B through another node unless a phrase ‘immediately transferred’ or ‘directly transferred’ is used.

Hereinafter, according to an example embodiment of the present disclosure, a vehicle display device in which a heat dissipation structure is built inside a metal plate disposed on a back surface of a display panel, thereby efficiently dissipating heat generated from the display panel is described in more detail.

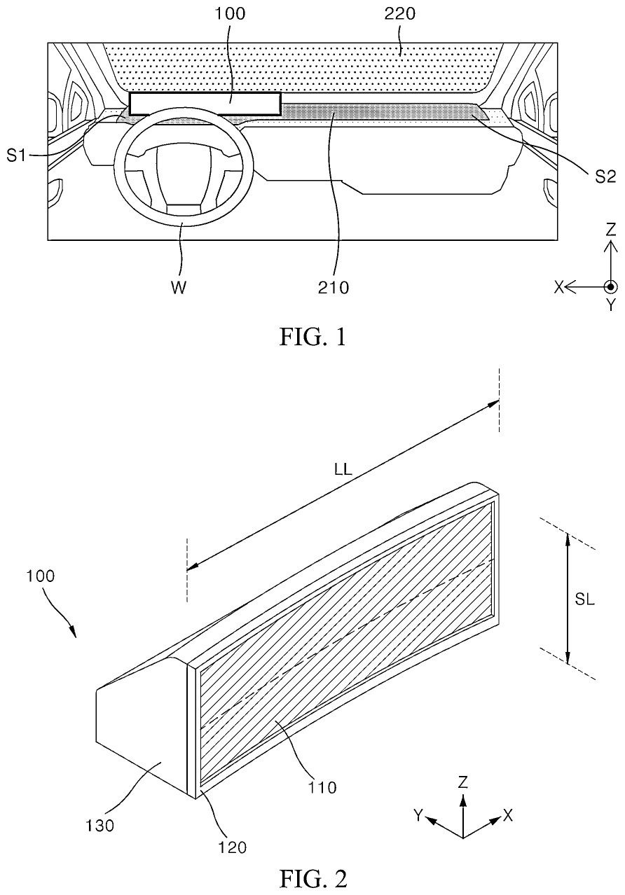

FIG. 1 is a diagram schematically showing a vehicle equipped with a vehicle display device according to an example embodiment of the present disclosure.

A frontward and upward direction defined in the present disclosure refers to a Z-axis direction, and a backward and downward direction refers to a −Z-axis direction.

Referring to FIG. 1, a vehicle according to some embodiments of the present disclosure includes a dashboard 210 adjacent to a bottom of a front glass 220 (or a windshield) and a vehicle display device 100 disposed on the dashboard 210.

The vehicle display device 100 may be disposed between one edge S1 and the other edge S2 of the dashboard 210. FIG. 1 illustrates that the vehicle display device 100 is disposed between a steering wheel W and the front glass 220. However, embodiments of the present disclosure are not limited thereto. Furthermore, the vehicle display device 100 may extend from one edge S1 to the other edge S2 of the dashboard 210. In this case, not only the driver but also the passenger in the passenger seat may view the image displayed on the vehicle display device 100.

The vehicle display device 100 may display images in a general image mode and a multi-view mode.

The vehicle display device 100 displays one image the general image mode as a general display device does. In this case, the vehicle display device 100 may display one image in a wide viewing angle range so that all viewers located in front of the device 100 may comfortably view the image. Thus, both the driver and the passenger in the passenger seat may view one image displayed on the vehicle display device 100.

The vehicle display device 100 may display a first image in a first direction and a second image in a second direction different from the first direction in the multi-view mode. The first direction may be a direction toward a position on top of the driver's gaze and may be a direction toward a position in front of and on top of the vehicle display device 100. The second direction may be the driver's gaze direction and may be a direction toward a position in front of and under the vehicle display device 100.

The front glass 220 is present in the first direction. Thus, the first image is directed to the front glass 220 and is thus displayed to the driver as a virtual image. Thus, a head up display (HUD) is realized. Furthermore, the driver is present in the second direction. Thus, the second image is visible to the driver in a real manner, that is, directly.

As discussed above, according to an example embodiment of the present disclosure, the vehicle display device 100 that displays the first image in the first direction toward the front windshield 200 and displays the second image in the second direction toward the driver in the multi-view mode is disposed on the dashboard 210 of the vehicle. As a result, according to an example embodiment of the present disclosure, the driver may obtain driving information from a plurality of images because the driver may view the first image in the head-up display manner and at the same time, may directly view the second image. This may increase the driver's driving convenience.

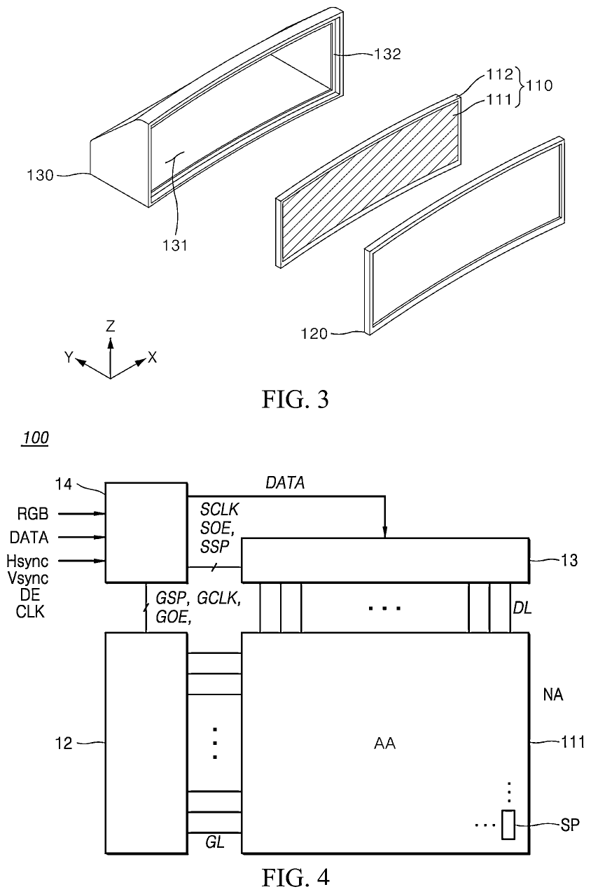

FIG. 2 is a drawing schematically showing an outer appearance of a vehicle display device according to an example embodiment of the present disclosure, and FIG. 3 is an exploded perspective view showing the vehicle display device according to an example embodiment of the present disclosure.

Referring to FIG. 2 and FIG. 3, the vehicle display device 100 according to an example embodiment of the present disclosure may have a long side and a short side.

A short side length SL of the vehicle display device 100 to be smaller than a short side length of the dashboard 210. a long side length LL of the vehicle display device 100 may be smaller than a length from one edge S1 to the other edge S2 of the dashboard 210, as shown in FIG. 1.

The vehicle display device 100 according to an example embodiment of the present disclosure may include a display module 110, a front cover 120, and a housing 130.

The display module 110 may include a display panel 111 and a rear cover 112. The display panel 111 may be mounted on the rear cover 112. The display panel 111 may have a front cover 120 as a front portion, and a rear cover 112 as a rear portion.

The display module 110 may be a liquid crystal display module or an organic light-emitting display module. The display module 110 directly displays an image using a liquid crystal display panel or an organic light-emitting display panel. This scheme has excellent outdoor visibility, viewing angle, resolution, and luminance, compared to an image projection scheme, and thus has high information transmission ability, and minimized change in visibility depending on the external environment (weather, or when wipers move).

As shown in FIG. 3, the display module 110 may include the display panel 111, a guide frame (not shown) supporting the display panel 111, a lower cover (not shown) that stores therein a backlight unit and supports the guide frame, and an upper case (not shown) covering a front edge of the display panel 111 and a side surface of the lower cover. When the display module 110 is embodied as the liquid crystal display module, the display module may further include the backlight unit (not shown) disposed on a lower surface of the display panel 111 so as to emit light thereto.

The display panel 111 may include one or more display areas. For example, the display panel 111 may include a first display area adjacent to the driver's seat, a second display area facing a separation area between the driver's seat and the passenger seat, and a third display area adjacent to the passenger seat.

The first display area may display at least one of measuring instrument data, around view data, and navigation data that are essential to the driver for safe vehicle driving. In particular, when the vehicle starts driving, the first display area may display the measuring instrument data.

The second display area may display any one of around view data, navigation data, and media data.

The third display area may display around view data, navigation data, and media data. In this regard, the media data corresponds to contents for the entertainment of the user riding on the passenger seat. For example, when the first display area displays the measuring instrument data, the third display area may display the media data.

Both opposing edges of the display panel 111 are bent backwards. In this regard, a reinforcing member that reinforces the bending of the display panel 111 may be disposed on an outside of the display panel 111. In this regard, the reinforcing member may include, for example, a micro coating layer. The micro coating layer may be referred to MCL.

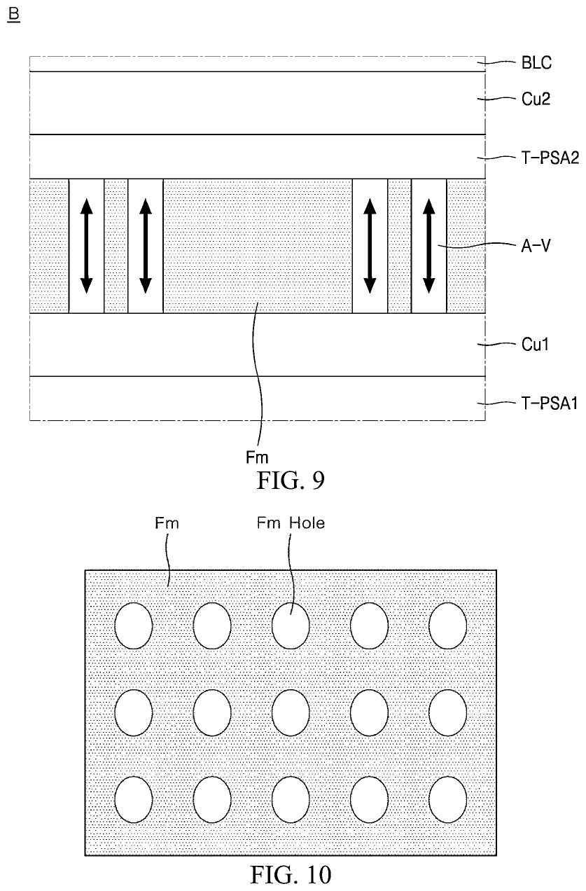

A polarizing layer (POL in FIG. 8) which will be described later may be attached to an upper surface of the display panel 111. The polarizing layer POL may have a transmission axis parallel to the long side of the display panel 111.

The display module 110 is stored in a storage space 131 of the housing 130 and displays an image based on image data supplied from a host system (not shown). The host system may supply the image data from at least one of a vehicle external camera (not shown), a driving image recording device (not shown), a navigation device (not shown), a portable terminal (not shown), an audio device (not shown), and a vehicle driving recording device (not shown) to the display module 110.

The front cover 120 may be provided in a form of a rectangular ring and may cover a front edge and a side surface of the display module 110.

The housing 130 may accommodate therein the display module 110. The housing 130 may be formed in a box shape having the storage space 131 and having an open front surface facing the driver's seat. A step-shaped module support surface 132 may be formed in a front edge of the storage space 131.

In an example embodiment of the present disclosure, an example in which the vehicle display device 100 is mounted on the dashboard 210 of the vehicle is described above. However, embodiments of the present disclosure are not limited thereto. The vehicle display device 100 may be mounted at another location inside the vehicle.

In another example, the display panel 111 may also be disposed on the steering wheel facing the driver's seat. In this case, the display panel 111 disposed on the dashboard 210 may be referred to as a first display panel unit, and the display panel 111 disposed on the steering wheel may be referred to as a second display panel unit. In this regard, the second display panel unit may include one or more display areas. When the first display panel unit includes the first to third display areas, the second display panel unit may include a fourth display area.

Furthermore, since the second display panel unit faces the driver's seat, the user riding on the driver's seat may view the second display panel unit without moving his or her eyes to the left or right. Accordingly, like the first display area of the first display panel unit, the fourth display area of the second display panel unit may display at least one of the measuring instrument data, the around view data, and the navigation data that are essential to the driver for safe vehicle driving.

In this regard, the media data corresponds to contents for the user's enjoyment. The around view data corresponds to imaging data obtained from at least one of a rear camera, a front camera, and a side camera. The navigation data corresponds to data from a driving system (or GPS system). The measuring instrument data includes various observed or predicted information about various conditions of the vehicle. For example, the measuring instrument data may include at least one piece of information among the remaining amount of energy source of the vehicle, the vehicle's driving speed, coolant temperature, remaining engine oil amount, engine abnormality, whether a brake is activated, whether warning lights are activated, whether seat belts are worn, cumulative driving distance, possible driving distance, and fuel efficiency.

In another example, the vehicle display device 100 according to an example embodiment of the present disclosure may be disposed on a center fascia located under the dashboard 210 and between the driver's seat and the passenger seat. In this case, the display panel 111 disposed on the center fascia may be referred to as a third display panel unit. Accordingly, when the first display panel unit includes the first to third display areas, and the second display panel unit includes the fourth display area, the third display panel unit may include a fifth display area.

The fifth display area disposed on the center fascia may display a control setting window that provides a user control interface for setting surrounding environment data or vehicle status. In this regard, the user control interface may include a user interface for controlling the image data displayed on the first and second display panel units, and a user interface for displaying or controlling the air conditioning status inside the vehicle. The surrounding environment data includes various information about the vehicle. By way of example, the surrounding environment data may include at least one piece of information among the illuminance outside the vehicle, the illuminance inside the vehicle, whether the user is riding on the driver's seat of the vehicle, whether the user is riding on the passenger seat of the vehicle, whether user input is performed using the control setting window, whether a physical shock to the vehicle has occurred, autonomous driving status, the vehicle's driving direction, and the vehicle's driving speed.

However, this is only an example, and it is obvious that the vehicle display device 100 provided in the vehicle may include at least one display panel unit disposed at various locations inside the vehicle. That is, at least one display panel unit of the vehicle display device 100 may further include a display panel unit disposed on the windshield, a display panel unit facing the rear seat, etc. in addition to the first, second, and third display panel units. Alternatively, at least one display panel unit of the vehicle display device 100 may include only the first display panel unit, or may include the first display panel unit and display panel units respectively disposed at various locations inside the vehicle.

In the vehicle display device 100 according to an example embodiment of the present disclosure, at least one display panel unit may provide a plurality of display areas. The plurality of display areas may include the first to third display areas disposed on the dashboard 210 of the vehicle, the fourth display area disposed on the steering wheel of the vehicle, and the fifth display area disposed on the center fascia located under the dashboard 210. The fourth display area may display the measuring instrument data or the around view data, and the fifth display area may display the control setting window that provides the user control interface for setting the status of the vehicle.

The vehicle display device 100 may calculate a weight of each of the display areas based on the surrounding environment data corresponding to an environment in which the display module 110 is installed, and image data of each display area. To this end, the vehicle display device 100 may include a weight calculator. The weight calculator may calculate the weight of each display area based on a predetermined weight setting period. In this way, the weight calculator periodically calculates the weight of each display area, thereby preventing an image quality of each display area from changing suddenly. As a result, deterioration of the display quality of the vehicle display device 100 and user inconvenience resulting therefrom may be prevented.

The weight may be a parameter for selecting a display area that displays image data that should be provided to the user as essential or preferential depending on the environment in which the vehicle display device 100 is installed. In an example, the weight calculator may calculate the respective weights of the plurality of display areas based on a weight lookup table indicating the respective weights of the image data corresponding to various conditions of the environment in which the vehicle display device is installed. In other words, the weight calculator may select a combination of the surrounding environment data and the image data of each display area from the weight lookup table, and may calculate the weight of each display area based on the selected combination. For example, when the vehicle display device 100 is installed inside the vehicle, the surrounding environment data may correspond to the driving state of the vehicle.

When the need for the driver to review the vehicle's position is relatively high, the weight calculator may assign the highest weight to the second display area that displays the navigation data based on the weight lookup table, the surrounding environment data, and the image data of each display area. In this regard, the weight calculator may assign the second highest weight to the first display area that displays the measuring instrument data and may assign the lowest weight to the third display area that displays the media data. In this regard, when the fourth display area displays the measuring instrument data, the weight calculator may assign the same weight as the weight assigned to the first display area to the fourth display area.

The weight calculator may assign the highest weight to the fifth display area that displays the control settings window only when the user input for vehicle environment settings is performed. In this regard, the weight calculator may assign the same weight lower than the weight assigned to the fifth display area to the third display area, the first and fourth display areas, and the second display area that display the media data, the measuring instrument data, and the navigation data. In cases other than this case, the weight calculator may assign the lowest weight to the fifth display area that displays the control setting window.

Alternatively, when the vehicle is in a stopped state, low-speed driving state, autonomous driving state, etc., the driving safety of the vehicle may be maintained even though the driver's attention to driving control is relatively low. Further, a priority may be given to the user on the passenger seat. In this case, the weight calculator may assign the highest weight to the second or third display area that displays the media data based on the weight lookup table, the surrounding environment data, and the image data of each display area. In this regard, the weight calculator may assign a relatively low weight to the first display area that displays the measuring instrument data or the second display area that displays the navigation data.

Alternatively, the weight calculator may assign the highest weight to the second display area that displays the around view data when the need for the driver to check the surrounding conditions of the vehicle for driving safety is relatively high. In this regard, the weight calculator may assign a relatively low weight to the first display area that displays the measuring instrument data.

Alternatively, the weight calculator may assign the highest weight to the first and fourth display areas that display the measuring instrument data when a very high level of driver attention is required for driving safety. In this regard, the weight calculator may assign a relatively low weight to the second display area that displays the navigation data.

When the control setting window is displayed in the fifth display area, the weight calculator may set the weight assigned to the fifth display area to be higher than the weight assigned to each of the first to fourth display areas.

Accordingly, the vehicle display device 100 may allocate power consumption reduced with a higher correction value to the first to fourth display areas to which the weight lower than the weight assigned to the fifth display area is assigned, and may allocate power consumption reduced with a lower correction value to the fifth display area to which a relatively higher weight is assigned.

FIG. 4 is a block diagram schematically showing an internal configuration of a vehicle display device according to an example embodiment of the present disclosure.

Referring to FIG. 4, the vehicle display device 100 according to an example embodiment of the present disclosure may include the display panel 111, a gate driver 12, a data driver 13, and a timing controller 14.

The display panel 111 may include a display area AA where at least one sub-pixel SP is disposed and a non-display area NA surrounding the display area.

The display panel 111 may be connected to a plurality of gate lines GL and data lines DL. A plurality of sub-pixels SP may be arranged in a matrix form in the display panel 111.

The gate driver 12 may drive the plurality of gate lines GL. That is, the gate driver 12 may supply a gate signal (scan signal) to the plurality of gate lines GL.

The data driver 13 may supply data voltage to the plurality of data lines DL.

The timing controller 14 may control the gate driver 12 and the data driver 13.

Although is not shown, the vehicle display device 100 may further include, in addition to the above-described components, a power management circuit that applies power to drive the display panel, a camera for photographing the external environment to the vehicle, and a black box that may store image data captured by the camera.

The display panel 111 may display an image based on the scan signal transmitted thereto from the gate driver 12 through the plurality of gate lines GL and the data voltage transmitted thereto from the data driver 13 through the plurality of data lines DL.

When the display module is embodied as the liquid crystal display module, the display panel 111 may include a liquid crystal layer formed between two substrates and may operate in a known mode such as a TN (Twisted Nematic) mode, a VA (Vertical Alignment) mode, a IPS (In Plane Switching) mode, and a FFS (Fringe Field Switching) mode. On the other hand, when the display module is embodied as the organic light-emitting display module, the display panel 111 may operate in a top emission scheme, a bottom emission scheme, or a dual emission scheme.

The display panel 111 may have the plurality of sub-pixels SP arranged in a matrix form. The sub-pixels SP may include sub-pixels SP emitting light of different colors, for example, a white sub-pixel, a red sub-pixel, a green sub-pixel, and a blue sub-pixel. An area of each sub-pixel SP may be defined by the data lines DL and the gate lines GL.

One sub-pixel SP may include a thin-film transistor TFT formed in an area where one data line DL and one gate line GL intersect each other, a light-emitting element such as an organic light-emitting diode that charges the data voltage, and a storage capacitor that is electrically connected to the light-emitting element to maintain the voltage thereof.

For example, when the vehicle display device 100 with a resolution of 2,160×3,840 is composed of four sub-pixels SP, that is, white, red, green, and blue sub-pixels, 2,160 gate lines GL may be provided, and 3,840 data lines DL may be connected to the four sub-pixels SP, such that a total of 3,840×4=15,360 data lines DL may be provided. Each sub-pixel SP may be disposed at each point where the gate lines GL and the data lines DL intersect each other.

The gate driver 12 may be controlled by the timing controller 14 so as to sequentially output the scan signal to the plurality of gate lines GL arranged in the display panel 111, thereby controlling an operation timing of each of the sub-pixels SP.

In the vehicle display device 100 with a resolution of 2,160×3,840, sequentially outputting the scan signal to the 2,160 gate lines GL in an order from a first gate line to a 2,160-th gate line may be referred to as 2,160 phase operation. Alternatively, sequentially outputting the scan signal on a four gate lines GL basis, such as sequentially outputting the scan signal to four gate lines including the first gate line to the fourth gate line and then sequentially outputting the scan signal four gate lines including the fifth gate line to the eighth gate line may be referred to as 4 phase operation. In other words, sequentially outputting the scan signal based on a N gate lines GL basis may be referred to as N-phase operation.

In this regard, the gate driver 12 may include one or more gate driving integrated circuits GDIC. Depending on a driving scheme, the gate driver may be located on only one side of the display panel 111 or on each of both opposing sides thereof. Alternatively, the gate driver 12 may be built into the bezel area of the display panel 111 and thus may be implemented in a GIP (Gate In Panel) form.

The data driver 13 receives sub-image data DATA from the timing controller 14 and converts the received sub-image data DATA into analog data voltage. Then, the data driver outputs the data voltage to each data line DL in accordance with a timing at which the scan signal is applied through the gate line GL. Thus, each sub-pixel SP connected to the data line DL displays a light-emission signal with brightness corresponding to the data voltage.

Likewise, the data driver 13 may include one or more source driving integrated circuits SDIC. The source driving integrated circuit SDIC may be connected to a bonding pad of the display panel 111 using a TAB (Tape Automated Bonding) scheme or a COG (Chip On Glass) scheme, or may be disposed directly on the display panel 111.

In some cases, each source driving integrated circuit SDIC may be integrated into the display panel 111. Furthermore, each source driving integrated circuit SDIC may be implemented in a COF (Chip On Film) manner. In this case, each source driving integrated circuit SDIC may be mounted on a circuit film and may be electrically connected to the data line DL of the display panel 111 through the circuit film.

The timing controller 14 supplies various control signals to the gate driver 12 and the data driver 13, and controls the operations of the gate driver 12 and the data driver 13. In other words, the timing controller 14 controls the gate driver 12 to output the scan signal according to a timing implemented in each frame. On the other hand, the timing controller 14 transmits the image data DATA transmitted thereto from the camera or the image data DATA transmitted thereto through the black box to the data driver 13.

In this regard, the timing controller 14 may receive, from the host system, the image data DATA and various timing signals which includes a vertical synchronization signal Vsync, a horizontal synchronization signal Hsync, a data enable signal DE, a main clock MCLK, etc.

The host system may include one or more of a TV Television system, a set-top box, a navigation system, a personal computer (PC), a home theater system, a mobile device, a wearable device, a camera 160, and a black box 170. In this regard, an example in which the timing controller 14 receives the image data DATA through the camera that may photograph the external environment to the vehicle or the black box that may store therein the image data DATA taken from the camera will be described below.

Accordingly, the timing controller 14 generates a control signal using the various timing signals received from the camera or the black box and transmits the control signal to the gate driver 12 and the data driver 13.

For example, the timing controller 14 outputs various gate control signals including a gate start pulse GSP, a gate clock GCLK, and a gate output enable signal GOE, etc. to control the gate driver 12. In this regard, the gate start pulse GSP controls a timing at which one or more gate driving integrated circuits GDIC start operating. Furthermore, the gate clock GCLK is a clock signal commonly input to one or more gate driving integrated circuits GDIC, and controls a shift timing of the scan signal. Furthermore, the gate output enable signal GOE specifies timing information of one or more gate driving integrated circuits GDIC.

Furthermore, the timing controller 14 outputs various data control signals including a source start pulse SSP, a source sampling clock SCLK, and a source output enable signal SOE, etc. to control the data driver 13. In this regard, the source start pulse SSP controls a timing at which one or more source driving integrated circuits SDICs constituting the data driver 13 start sampling data. The source sampling clock SCLK is a clock signal that controls a timing at which the source driving integrated circuit SDIC samples the data. The source output enable signal SOE controls an output timing of the data driver 13.

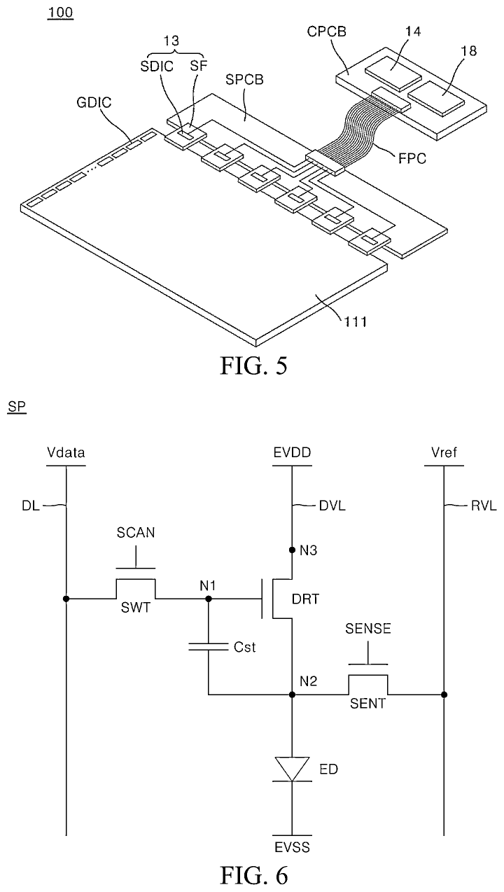

This vehicle display device 1005 may include the power management circuit (18 in FIG. 5) that supplies various voltages or currents to the display panel 111, the gate driver 12, the data driver 13, or controls the various voltages or currents to be supplied thereto. The power management circuit 18 adjusts a direct current input voltage to generate power required to drive the display panel 111, the gate driver 12, and the data driver 13.

FIG. 5 is a diagram schematically showing a configuration of a vehicle display device according to an example embodiment of the present disclosure.

Referring to FIG. 5, the vehicle display device 100 according to an example embodiment of the present disclosure relates to an example in which the source driving integrated circuit SDIC included in the data driver 13 is implemented in the COF (Chip On Film) scheme among various schemes TAB, COG, COF, etc. and the gate driver 12 is implemented in the GIP (Gate In Panel) scheme among various schemes TAB, COG, COF, GIP, etc.

Each of one or more gate driving integrated circuits GDIC included in the gate driver 12 may be mounted on a gate film GF. One side of the gate film GF may be electrically connected to the display panel 111. Furthermore, wirings for electrically connecting the gate driving integrated circuit GDIC and the display panel 111 to each other may be disposed on a top of the gate film GF.

Likewise, each of one or more source driving integrated circuits SDICs included in the data driver 13 may be mounted on the source film SF. One side of the source film SF may be electrically connected to the display panel 111. Furthermore, wiring for electrically connecting the source driving integrated circuit SDIC and the display panel 111 to each other may be disposed on a top of the source film SF.

This vehicle display device 100 may include at least one source printed circuit board SPCB, and a control printed circuit board CPCB for mounting control parts and various electrical devices thereon, for connection between a plurality of source driving integrated circuits SDIC and other devices.

In this regard, the other side of the source film SF on which the source driving integrated circuit SDIC is mounted may be connected to at least one source printed circuit board SPCB. That is, one side of the source film SF on which the source driving integrated circuit SDIC is mounted may be electrically connected to the display panel 111, and the other side thereof may be electrically connected to the source printed circuit board SPCB.

The timing controller 14 and the power management circuit 18 may be mounted on the control printed circuit board CPCB. The timing controller 14 may control the operations of the data driver 13 and the gate driver 12. The power management circuit 18 may supply the driving voltage or current to the display panel 111, the data driver 13, and the gate driver 12, and may control the voltage or current supplied thereto.

The at least one source printed circuit board SPCB and the control printed circuit board CPCB may be connected to each other through at least one connection member. The connection member may be embodied as, for example, a flexible printed circuit FPC, a flexible flat cable FFC, etc. In this regard, a design of the connection member connecting the at least one source printed circuit board SPCB and the control printed circuit board CPCB to each other may vary depending on a size and a type of the vehicle display device 100. Furthermore, the at least one source printed circuit board SPCB and the control printed circuit board CPCB may be integrated into one printed circuit board.

In the vehicle display device 100 as configured as above, the power management circuit 18 supplies the driving voltage required to drive the display panel to the source printed circuit board SPCB through the flexible printed circuit FPC or the flexible flat cable FFC. The driving voltage delivered to the source printed circuit board SPCB is supplied to the display panel 111 through the source driving integrated circuit SDIC such that a specific sub-pixel SP in the display panel 111 emits light or is sensed.

In this regard, each sub-pixel SP disposed in the display panel 111 may be composed of an organic light-emitting diode as a light-emitting element, and a circuit element such as a driving transistor for driving the light-emitting element.

A type and the number of circuit elements constituting each sub-pixel SP may be determined in various ways depending on a function and a design method thereof.

FIG. 6 is a diagram showing an example circuit configuration of the sub-pixel SP of FIG. 4 in a vehicle display device according to an example embodiment of the present disclosure.

Referring to FIG. 6, one sub-pixel SP in the vehicle display device 100 according to an example embodiment of the present disclosure may include one or more transistors and a capacitor. An organic light-emitting diode may act as a light-emitting element ED.

For example, the sub-pixel SP may include a driving transistor DRT, a switching transistor SWT, a sensing transistor SENT, a storage capacitor Cst, and the light-emitting element ED.

The driving transistor DRT has a first node N1, a second node N2, and a third node N3. The first node N1 of the driving transistor DRT may be a gate node to which the data voltage Vdata is applied from the data driver 13 through the data line DL when the switching transistor SWT is turned on. The second node N2 of the driving transistor DRT may be electrically connected to an anode electrode of the light-emitting element ED, and may be a source node or a drain node. The third node N3 of the driving transistor DRT may be electrically connected to a driving voltage line DVL to which a driving voltage EVDD is applied, and may be the drain node or the source node.

In this regard, during a display operation period, the driving voltage EVDD required to display the image may be supplied through the driving voltage line DVL. For example, the driving voltage EVDD required to display the image may be 27V.

The switching transistor SWT may be electrically connected to and disposed between the first node N1 of the driving transistor DRT and the data line DL, and may operate based on the scan signal SCAN supplied to the gate node thereof through the gate line GL when the gate line GL is connected to the gate node. Furthermore, when the switching transistor SWT is turned on, the data voltage Vdata supplied through the data line DL is transmitted to the gate node of the driving transistor DRT, such that the operation of the driving transistor DRT is controlled.

The sensing transistor SENT may be electrically connected to and disposed between the second node N2 of the driving transistor DRT and a reference voltage line RVL, and may operate based on a sense signal SENSE supplied to a gate node thereof through the gate line GL when the gate line GL is connected to the gate node. When the sensing transistor SENT is turned on, a sensing reference voltage Vref supplied through the reference voltage line RVL is transmitted to the second node N2 of the driving transistor DRT.

That is, the switching transistor SWT and the sensing transistor SENT may be controlled such that a voltage of each of the first node N1 and the second node N2 of the driving transistor DRT may be controlled, and thus, the current may be supplied to the light-emitting element ED to drive the light-emitting element ED.

The gate nodes of the switching transistor SWT and the sensing transistor SENT may be connected together to one gate line GL or may be connected to different gate lines GL, respectively. In this regard, a structure where the switching transistor SWT and sensing transistor SENT are connected to different gate lines GL, respectively, is shown in the drawing by way of example. In this case, the switching transistor SWT and the sensing transistor SENT may be independently controlled based on the scan signal SCAN and the sense signal SENSE transmitted thereto through the different gate lines GL, respectively.

In another example, when the switching transistor SWT and the sensing transistor SENT are connected to one gate line GL, the switching transistor SWT and the sensing transistor SENT may be controlled simultaneously based on the scan signal SCAN or the sense signal SENSE transmitted thereto through one gate line GL. In this case, an aperture ratio of the sub-pixel SP may increase.

The transistor disposed in the sub-pixel SP may be embodied as an n-type transistor or a p-type transistor. A case in which the transistor disposed in the sub-pixel SP is embodied as the n-type transistor is shown in the drawing by way of example.

The storage capacitor Cst is electrically connected to and disposed between the first node N1 and the second node N2 of the driving transistor DRT and maintains the data voltage Vdata for one frame.

This storage capacitor Cst may be connected to and disposed between the first node N1 and the third node N3 of the driving transistor DRT depending on a type of the driving transistor DRT. The anode electrode of the light-emitting element ED may be electrically connected to the second node N2 of the driving transistor DRT. A base voltage EVSS may be applied to the cathode electrode of the light-emitting element ED.

In this regard, the base voltage EVSS may be a ground voltage or a voltage higher or lower than the ground voltage. Furthermore, the electromotive voltage EVSS may vary depending on a driving state. For example, the base voltage EVSS at a time of a display operation and the base voltage EVSS at a time of a sensing operation may be set to be different from each other.

For example, a structure of the sub-pixel SP as described above is a 3T (Transistor) 1C (Capacitor structure). This is only an example for illustration. The sub-pixel may further include one or more transistors. Depending on a case, the sub-pixel may further include one or more capacitors. Alternatively, the plurality of sub-pixels SP may have the same structure. Alternatively, some of the plurality of sub-pixels SP may have different structures.

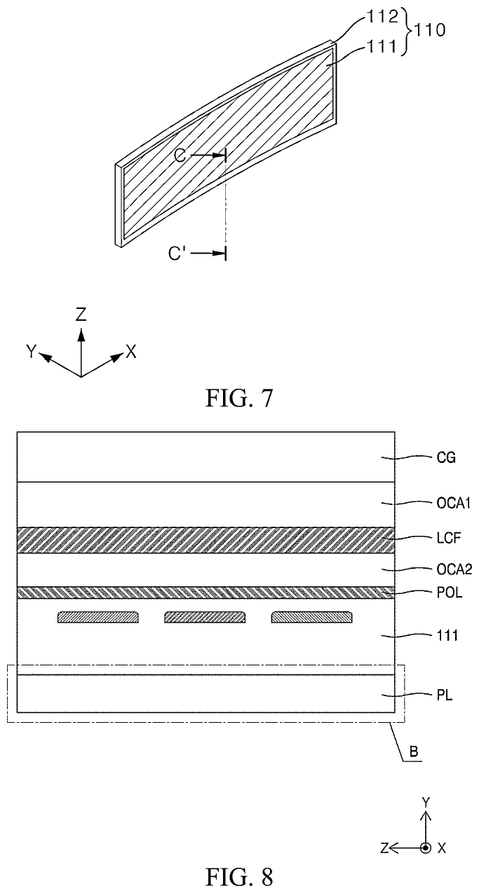

FIG. 7 is a diagram showing a cutting line cutting the display module according to an example embodiment of the present disclosure, and FIG. 8 is a cross-sectional view of the display module according to an example embodiment of the present disclosure cut along the cutting line C-C′.

Referring to FIG. 7, the display module 110 according to an example embodiment of the present disclosure may include the display panel 111 mounted on the rear cover 112.

Referring to FIG. 8, the vehicle display device 100 according to an example embodiment of the present disclosure may include the display panel 111 and a plate PL.

Since the vehicle display device 100 is mounted on the vehicle's dashboard 210, the display panel 111 may be disposed on the vehicle's dashboard 210.

The display panel 111 may include a display area AA where a plurality of sub-pixels SP are arranged and a non-display area NA surrounding the display area, as shown in FIG. 4.

In FIG. 8, the plate PL may be disposed under the display panel 111 and may support the display panel 111.

The display panel 111 may include, for example, a first sub-pixel R that emits red light, a second sub-pixel G that emits green light, and a third sub-pixel B that emits blue light. The display panel 111 according to an example embodiment of the present disclosure is not limited thereto. Although not shown, the display panel 111 may further include a fourth sub-pixel W that emits white light.

As shown in FIG. 9, the plate PL may include a plurality of metal layers Cu1 and Cu2, and may further include a foam layer Fm disposed between the plurality of metal layers Cu1 and Cu2. An air vent A-V capable of heat exchange may be formed in the foam layer Fm. FIG. 9 is a structural diagram showing a B portion of FIG. 8 in more detail in the display module according to an example embodiment of the present disclosure.

Referring to FIG. 9, the plate PL according to an example embodiment of the present disclosure may include the first metal layer Cu1 disposed on top of a first thermally-conductive pressure-sensitive adhesive layer T-PSA1, and the foam layer Fm on top of the first metal layer. Furthermore, the plate PL may further include a second thermally-conductive pressure-sensitive adhesive layer T-PSA2 disposed on top of the foam layer, the second metal layer Cu2 disposed on top of the second thermally-conductive pressure-sensitive adhesive layer, and a black coating layer BLC disposed on top of the second metal layer Cu2. Each of the first thermally-conductive pressure-sensitive adhesive layer T-PSA1 and the second thermally-conductive pressure-sensitive adhesive layer T-PSA2 may include graphite powders PSA.

The black coating layer BLC may be made of a plastic material including at least one of polycarbonate (PC), polyimide (PI), polyethylene naphthalate (PEN), and polyethylene terephthalate (PET).

The black coating layer BLC may be disposed on top of the second metal layer Cu2 as the uppermost layer of the plate PL, such that the display module 110 has heat dissipation performance through heat conduction and radiation, and an emissivity thereof is approximately 0.9.

The foam layer Fm may have at least two air vents A-V extending in a vertical direction and spaced from each other in a horizontal direction.

The foam layer Fm may include multiple holes as shown in FIG. 10 in addition to two or more air vents A-V. FIG. 10 is a diagram showing an example in which multiple holes are formed inside the plate according to an example embodiment of the present disclosure. As the multiple holes are formed inside the plate PL, heat generated during the operation of the display module 110 may be conducted and circulated through the multiple holes. The plurality of holes may be formed inside the foam layer Fm disposed between the first metal layer Cu1 and the second metal layer Cu2, thereby allowing the air to pass through the plurality of holes such that the heat may be transferred between the two metal layers Cu1 and Cu2.

Each of the first metal layer Cu1 and the second metal layer Cu2 may include copper (Cu) which has high thermal conductivity.

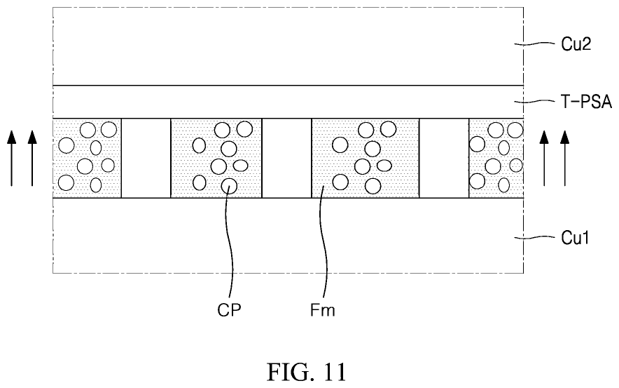

Furthermore, the foam layer Fm may include carbon powders CP as shown in FIG. 11 for heat conduction. FIG. 11 is a diagram showing an example in which the foam layer Fm containing the carbon powders disposed inside the plate according to an example embodiment of the present disclosure. As shown in FIG. 11, the carbon powders CP may be included inside the foam layer Fm, so that the thermal conductivity between the first metal layer Cu1 and the second metal layer Cu2 may be improved through the carbon powders CP.

The plate PL of the above-described structure may be located between a glass and a set frame or between the glass and the flexible printed circuit board FPC.

Although is not shown in the drawing, a guide holder may be disposed under the first thermal pressure-sensitive adhesive layer T-PSA1, and the rear cover may be disposed under the guide holder. In this regard, the guide holder may be fixed to the rear cover in a screw fastening manner.

In this regard, the rear cover has a flat bottom in the display area AA and the non-display area NA, and has a height sized such that a top of the rear cover contacts the cover glass CG at an end of the non-display area NA, and may be bonded to the cover glass CG through a connecting member.

In this regard, the connecting member may be made of an elastic material including a foam tape or a foam pad, or may include a tape with a shock absorbing function or a double-sided tape with conductivity.

Furthermore, the guide holder may receive a source printed circuit board (PCB) therein, and the source PCB may be electrically connected to the display panel 111 through the flexible printed circuit board FPC.

Referring again to FIG. 8, the polarizing layer POL may be disposed on top of the display panel 111, a first optical adhesive layer (Optical Clear Adhesive) OCA1 may be disposed on top of the polarizing layer, and a light control film LCF may be disposed on top of the first optical adhesive layer. Furthermore, a second optical adhesive layer OCA2 may be disposed on top of the light control film LCF, and the cover glass CG may be disposed on top of the second optical adhesive layer.

The cover glass CG may be made of one of polymethylmethacrylate (PMMA), polycarbonate (PC), cycloolefin polymer (COP), polyethylene terephthalate (PET), polyimide (PI), and polyaramid (PA) having impact resistance and light transparency.

As described above, the display module 110 which has the plate PL including the air vents A-V and the plurality of holes as above-described may lower the surface temperature of the cover glass CG by 1 degree C.

In one example, the foam layer Fm may have a thickness of 120 micrometers (μm) or smaller but greater than zero micrometers.

Each of the first metal layer Cu1 and the second metal layer Cu2 may have a thickness of 70 micrometers (μm) or smaller but greater than zero micrometers.

Each of the first thermally-conductive pressure-sensitive adhesive layer T-PSA1 and the second thermally-conductive pressure-sensitive adhesive layer T-PSA2 may have a thickness of 50 micrometers (μm) or smaller but greater than zero micrometers.

The foam layer Fm may be made of an elastic material including a foam tape or a foam pad or may include a tape with a shock absorbing function or a double-sided tape with conductivity. For example, the double-sided conductive tape may include an upper adhesive layer, a lower adhesive layer, and a conductive layer between the upper adhesive layer and the lower adhesive layer. The upper and/or lower adhesive layer may also contain a conductive material.

Furthermore, the foam layer Fm may include urethane, poly urethane, or acrylic. The acrylic may include acrylic acid or acrylic resin. The acrylic resin may include polymethyl methacrylate (PMMA), polyacrylonitrile (PAN), polyacrylic acid (PAA), etc.

Each of the first and second optical adhesive layers OCA1a and OCA2 may be composed of at least one or more layers made of at least one of a transparent optical adhesive OCA (Optical Clear Adhesive), a transparent optical resin OCR (Optical Clear Resin), or a pressure sensitive adhesive (PSA).

Each of the first and second optical adhesive layers OCA1a and OCA2 may have a thickness of, for example, 100 to 300 μm. When the optical adhesive layer OCA has a thickness smaller than 100 μm, the adhesive strength becomes weak, making it difficult to modularize the cover glass CG and the plate PL. When the optical adhesive layer OCA has a thickness exceeding 300 μm, the vehicle display device 100 may not be bent.

The cover glass CG protects the display panel 111 from external shock and transmits light emitted from the display panel 111 therethrough so that the image displayed on the display panel 111 is visible to a viewer in front of the panel 111. Embodiments of the present disclosure are not limited thereto.

The polarizing layer POL prevents the contrast ratio CR from decreasing due to external light. In the vehicle display device 100 according to the present disclosure, the polarizing layer POL that blocks external light incident from the outside is disposed in the transmission direction of the light emitted through the display panel 111 when the OLED panel operates in a driving mode in which the OLED displays an image. Thus, the contrast ratio is improved.

The rear cover may include a metal. Accordingly, the rear cover made of a metal material may accommodate therein the components including the display panel 111 disposed on the back surface of the cover glass CG, and also may protect the components.

In one example, when an impact due to an external force exceeding a certain pressure is applied to the vehicle display device 100 or the rear cover, the impact may be alleviated by the rear cover or the module support surface 132.

Accordingly, the cushioning effect of the rear cover or the module support surface 132 prevents cracks from occurring in the display panel 111 and protects the display panel 111.

The vehicle display device 100 according to an example embodiment of the present disclosure refers to a display device having flexibility, and may include a bendable display device, a rollable display device that can be rolled, an unbreakable display device that does not break, and a foldable display device that can be folded.

The driver integrated circuit may be implemented as a TFT (thin film transistor) in the non-display area NA. This driver integrated circuit may be referred to as a GIP (gate-in-panel) circuit. The GIP circuit includes a gate driver of a GIP structure, wherein the gate driver is embodied as a bottom gate type thin-film transistor (BG-T), and a source and drain metal film of a bridge line extends so as to connected to a drain electrode of the BG thin-film transistor.

Moreover, some components, such as the data driver IC may be mounted on a separate printed circuit board, or may be coupled to a connection interface (pads/bumps, pins, etc.) disposed in the non-display area NA using a circuit film such as FPCB (flexible printed circuit board), COF (chip-on-film), or TCP (tape-carrier-package). The non-display area NA may be bent along with the connection interface, so that the printed circuit (COF, PCB, etc.) may be disposed on the rear surface (or the back surface) of the vehicle display device 100.

The vehicle display device 100 according to the present disclosure may include various additional components for generating various signals or driving the pixel PX in the display area. The additional components to drive the pixel may include an inverter circuit, a multiplexer, an electrostatic discharge circuit. The vehicle display device 100 according to the present disclosure may include additional components related to functions other than the function of driving the pixel. For example, the vehicle display device 100 according to the present disclosure may include additional components that provide a touch sensing function, a user authentication function such as fingerprint recognition, a multi-level pressure sensing function, and a tactile feedback function. The above-mentioned additional components may be disposed in an external circuit connected to the non-display area NA and/or the connection interface.

According to the present disclosure, several portions of the vehicle display device 100 may be bent along a bending line. The bending line may extend transversely, longitudinally, or diagonally. Accordingly, the vehicle display device 100 according to an example embodiment of the present disclosure may be bent in a combination of the transverse, longitudinal and diagonal directions based on a required design.

According to the present disclosure, one or more corner edges of the vehicle display device 100 may be bent along the bending line so as to be away from a central portion. The bending line may be disposed closer to the edge of the vehicle display device 100, but may extend across the central portion, or may extend diagonally from one or more corners of the vehicle display device 100. This structure may enable the vehicle display device 100 to be embodied as a foldable display device or a display device in which an image is displayed from each of both folded surfaces facing each other.

Since one or more portions of the vehicle display device 100 may be bent, the vehicle display device 100 according to the present disclosure may be divided into a substantially flat area and a curved area. One portion of the vehicle display device 100 may be referred to as a substantially flat area. One portion of the vehicle display device 100 may be bent at a predetermined angle, and this portion may be referred to as a bent area or a curvature area. The curvature area includes a bent section that is actually bent at a predetermined curvature radius.

The term “substantially flat” means that the substantially flat area includes a portion which is not perfectly flat. For example, a concave central portion and a convex central portion may belong to the substantially flat area in some embodiments. One or more bent sections may be present next to the concave central portion or the convex central portion, and are bent inwardly or outwardly at an angle relative to a bending axis along the bending line. The curvature radius of the curvature area is smaller than that of the flat area. In other words, the term “substantially flat area” means a portion with a smaller curvature than that of a portion adjacent thereto.

Depending on a position of the bending line, a portion on one side of the bending line is positioned toward the center of the vehicle display device 100, while a portion on the other side of the bending line is positioned toward the edge of the vehicle display device 100. A portion positioned toward the center of the vehicle display device 100 may be referred to as a central portion, and a portion positioned toward the edge of the vehicle display device 100 may be referred to as an edge portion. The central portion of the vehicle display device 100 may be substantially flat, and the edge portion may be a bent section. However, this is not always true. The substantially flat area may also be disposed in the edge portion. Further, in some shapes of the vehicle display device 100, the bent section may be disposed between two substantially flat areas.

When the non-display area NA is bent, the non-display area NA may be invisible or minimally visible to a viewer in front of the vehicle display device 100. A portion of the non-display area NA visible to the view in front of the vehicle display device 100 may be screened with a bezel. The bezel may be formed as a stand-alone structure, or as a housing or another suitable element. A portion of the non-display area NA visible to the view in front of the vehicle display device 100 may be hidden under an opaque mask layer such as a black ink layer made of black ink (e.g., a polymer filled with carbon black). Such an opaque mask layer may be disposed on various layers (e.g., a touch sensor layer, a polarization layer, a cover layer, and the like) included in the vehicle display device 100.

In some embodiments, the bent section of the vehicle display device 100 may include a display area capable of displaying an image. That is, the bending line may be disposed in the display area so that at least some of pixels of the display area are included in the bent section.

As described above, according to an example embodiment of the present disclosure, the vehicle display device may be realized in which the plurality of metal layers constitute the plate of the display panel in the display module mounted on the dashboard of the vehicle, and the foam layer having the air vent capable of heat exchange formed therein is disposed between adjacent ones of the plurality of metal layers.

The above description has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A vehicle display device, comprising:
a display panel disposed on a dashboard of a vehicle, wherein the display panel includes a display area in which a plurality of sub-pixels are arranged, and a non-display area surrounding the display area; and
a plate disposed under the display panel so as to support the display panel,
wherein the plate includes a plurality of metal layers, and further includes a foam layer disposed between adjacent ones of the plurality of metal layers, wherein the foam layer has an air vent formed therein.

2. The vehicle display device of claim 1, wherein the plate includes:
a first thermally-conductive pressure-sensitive adhesive layer;
a first metal layer disposed on the first thermally-conductive pressure-sensitive adhesive layer;
a second thermally-conductive pressure-sensitive adhesive layer disposed on the foam layer;
a second metal layer disposed on the second thermally-conductive pressure-sensitive adhesive layer; and
a black coating layer disposed on the second metal layer,
wherein the foam layer is disposed on the first metal layer.

3. The vehicle display device of claim 2, wherein the black coating layer is made of a plastic material including at least one of polycarbonate, polyimide, polyethylene naphthalate, and polyethylene terephthalate.

4. The vehicle display device of claim 1, wherein the foam layer includes at least two or more air vents disposed in a horizontal direction, and each of the at least two or more air vents is formed in a vertical direction.

5. The vehicle display device of claim 4, wherein the foam layer includes a plurality of holes in addition to the at least two or more air vents.

6. The vehicle display device of claim 2, wherein each of the first metal layer and the second metal layer includes copper (Cu).

7. The vehicle display device of claim 1, wherein the foam layer contains carbon powders.

8. The vehicle display device of claim 2, wherein a guide holder is disposed under the first thermally-conductive pressure-sensitive adhesive layer,
wherein a rear cover is disposed under the guide holder,
wherein the guide holder is fixed to the rear cover in a screw fastening manner.

9. The vehicle display device of claim 8, wherein the guide holder receives therein a source printed circuit board (PCB),
wherein the source PCB is electrically connected to the display panel through a flexible printed circuit board (FPCB).

10. The vehicle display device of claim 8, wherein a polarizing layer is disposed on the display panel,
wherein a first optical adhesive layer is disposed on the polarizing layer,
wherein a light control film is disposed on the first optical adhesive layer,
wherein a second optical adhesive layer is disposed on the light control film,
wherein a cover glass is disposed on the second optical adhesive layer.

11. The vehicle display device of claim 10, wherein the rear cover has a flat bottom in the display area and the non-display area, and has a height sized such that a top of the rear cover contacts the cover glass in an end of the non-display area, and
wherein the rear cover is bonded to the cover glass through a connecting member.

12. The vehicle display device of claim 11, wherein the connecting member includes a foam tape or a foam pad, or includes a tape made of an elastic material or a conductive double-sided tape.

13. The vehicle display device of claim 10, wherein the cover glass is made of one of polymethyl methacrylate, polycarbonate, cycloolefin polymer, polyethylene terephthalate, polyimide, and polyaramid.

14. The vehicle display device of claim 1, wherein the foam layer has a thickness of 120 micrometers or smaller but greater than zero micrometers.

15. The vehicle display device of claim 2, wherein each of the first metal layer and the second metal layer has a thickness of 70 micrometers or smaller but greater than zero micrometers.
